(19) United States
(12) Patent Application Publication
(10) Pub. No.: US 2023/0280649 A1
(43) Pub. Date: Sep. 7, 2023

(54) WELDING METHOD FOR CREATING AN UPSCALED MASTER

(71) Applicant: MORPHOTONICS HOLDING B.V., Veldhoven (NL)

(72) Inventors: Leon Willem VELDHUIZEN, Utrecht (NL); Jan Matthijs TER MEULEN, Eindhoven (NL); Bram Johannes TITULAER, Veldhoven (NL)

(21) Appl. No.: 18/005,835

(22) PCT Filed: Jul. 14, 2021
(86) PCT No.: PCT/EP2021/069609

§ 371 Date: Jan. 17, 2023

(30) Foreign Application Priority Data
Jul. 31, 2020 (EP) 20188863.3

(51) Int. Cl. G03F 7/00; G03F 7/021; G03F 7/20

(52) U.S. Cl. CPC G03F 7/0002; G03F 7/0217; G03F 7/2004; G03F 7/70166; G03F 7/0027

(57) ABSTRACT

A method is for creating an upscaled master for an imprinting process. At least two masters are welded together, whereby at least one master includes at least partially at least one textured area. A photosensitive resin is at least applied between the two masters, whereby light of a light source is guided within a waveguiding system and cures the photosensitive resin at least between the at least two submasters when the photosensitive resin comes into contact with the waveguiding system. An upscaled master is obtained by the method, and an imprinting product is obtained from the upscaled master. An apparatus makes an upscaled master by carrying out the method.

### DESCRIPTION

The invention relates to a method for fabricating an upscaled nano and/or microtextured master mold.

Nano and microtextured surfaces can be found in an increasing number of applications. In those applications the textured surfaces can either increase the functionality of a device (e.g. the efficiency of a photovoltaic module) or enable completely new functionalities (e.g. holographic displays). These textured surfaces are often applied to a product by copying the texture from a master using methods such as injection molding or nanoimprint lithography.

The fabrication of a master is often costly and time-consuming. Furthermore, mastering technologies are limited in the maximum surface area on which the texture can be applied. Some applications require to have a textured surface area that is beyond the limit of the mastering technology. For these applications, a smaller master could be scaled up to fulfill the dimension requirements. For other applications, it would be possible to originate a master with the required textured surface area, but a scaled-up master is preferred for economic reasons. For example, a scaled-up master could be used to replicate multiple smaller products per replication cycle. Most methods for scaling up a textured master can be divided into two categories.

The first category consists of methods that use step-and-repeat to print (usually identical) textured patterns multiple times on a larger substrate. The printed sub cells are commonly either separated by an untextured band, such as described in patent US20130153534A1, or are overlapping with each other, such as described by M. K. Kwak et al. Material Horizons Vol. 2, 2015, p. 86-90 (doi:10.1039/c4mh00159a). In both examples, in which UV nanoimprint lithography is used as imprint technology, there is a significant challenge to prevent UV-curable resin from flowing to undesired locations, causing cross-contamination between sub cells. This challenge puts limits to the types of texture, imprint pressure and resin that can be used.

The second category for fabricating an upscaled master consists of methods that physically splice multiple smaller masters together to form a upscaled master such as described in patent CN 105911815 and unpublished patent application EP 19202151.7 in the name of the applicant. In this approach, the risk of cross-contamination between sub cells is usually absent. However, the different masters will be connected by seams that can disturb the appearance of the scaled-up texture and which might interfere with the subsequent imprint process and/or could degrade over time. It is therefore often desired to obtain smooth, thin and durable seams. Patent CN 105911815 describes a method for achieving high-quality seams by using peelable adhesive tape for sealing and pasting a seam, while filling the seam with curable resin from the rear. Patent CN107121890A describes a method to create a large-area nano mold using photocurable resin on a transparent substrate using shading strips (e.g. metal or black resin) in the seam region. The uncured resin and shading strips can be removed after the imprinting.

In document KR 2012/0082266 a side bonding process is disclosed for creating a large area nano template. For this process a curable resin is used in-between different units. Document US 2016/0033818 teaches the manufacturing of large-sized pattern, whereby a plurality of pattern structures units is on the same plane and is connected via a resin in-between the units.

Document US 2018/0113242 discloses a method for manufacturing a pattern structure. Main focus of this document is a process in which a wafer is cut into different surfaces. However, this document also discloses that different unit pattern structures are aligned together. For a combination of different unit pattern structures, a liquid resin is prepared between a first and a second unit pattern structures, whereby the resin is a thermosetting or a photocurable resin.

The current invention describes an alternative method to physically weld multiple master together in a controllable way that results in welding seams with high optical and mechanical quality.

As a consequence, the invention pertains to a method for creating an upscaled master for an imprinting process. At least two masters are welded together, whereby at least one master comprises at least one textured area. A photosensitive resin is at least applied between the at least two masters, whereby light of a light source is guided within a waveguiding system and cures the photosensitive resin at least between the at least two submasters when the photosensitive resin comes into contact with the waveguiding system.

The method entails the placement of multiple textured (sub)master in close proximity to each other and in close proximity to or in direct contact with an optical waveguide system. Ultraviolet and/or visible light is coupled into the wave guide at one or multiple edges of the waveguide system or via one or more in-coupling structures. Photocurable resin that is sensitive to the light in the waveguide system is applied at the seam from the rear interface of the (sub)masters where it will flow into the seam area under the influence of capillary and/or gravitational force. When the resin has locally come into contact with the waveguide of the waveguiding system, light from the waveguide can escape and cures the resin in a controllable manner, before the resin might spread (undesirably) along the (textured) interfaces of the masters. For this to work, the refractive index of the resin in uncured condition differs from the refractive index of the waveguide material with a value of preferably less than 0.2 more preferably less than 0.1 and most preferably less than 0.05 in order to be able to disrupt total internal reflection of light within the wave guiding material. When the resin is cured, a welding seam is created between the two masters. When the welding process is completed, a backing plate or sheet can be optionally attached to the rear of the upscaled master after which the waveguide can be removed from the upscaled master.

The obtained upscaled master consists of multiple smaller units (masters) that are welded together to form a larger master array. The splices, or welding seams, between the smaller masters are made of photo-curable resin that is brought into contact with light of an optical waveguiding system, resulting in smooth and durable seams. Thus, also the imprinting product obtained is of higher quality compared to those of the prior art, with less variation in seam height and width.

The invention further relates to an imprinted product that are obtained from the upscaled master.

According to claim 1 at least two masters are welded together. However, the upscaled master may comprise more than three, four, five or six masters, which are welded together to form the upscaled master. At least one of the masters comprises at least partially a textured area. The textured area has a relief pattern, which is the inverse structure of the imprinting texture on a substrate. In one embodiment, all or more than one, preferably two, more preferred three and most preferred more than half of the masters comprise at least partially a textured area. The textured area may extend over the entire master area or only over parts of the masters. If the textured area extends only over partial areas of a master, preferably at least 60%, more preferred at least 80%, and most preferred at least 90% of the master area comprises the textured area. It is also possible to use masters which have different textured areas (this means different relief patters) and/or the textured areas have different sizes (this means the masters differ from each other by the size of the textured area).

In one embodiment the at least one master is positioned such that the at least one textured area of the at least one master is oriented towards the waveguiding systems and/or at least one of the masters is at least partially in contact with the waveguiding system. The term “partially in contact” preferably means in direct contact. In one preferred embodiment at least one master comprises a textured area and the textured area of the at least one master is in direct contact with the waveguiding system. The term “direct contact” means that the textured area and/or the master is in physical contact with the waveguiding system, no further material (layer, air) is present between waveguiding system and textured area.

Due to this arrangement, the light of the waveguiding system can escape directly when the resin comes into contact with the waveguiding system and cures the resin rapidly without any delay. Thus, an unwanted spreading of the resin over parts of the masters (for example over the textured area) can be prevented. Due to the preferred arrangement of the master faced with the textured area to the waveguiding system, the resulting welding seam is approximately at an even level to the height of the textured area. Thus, during the imprinting process, the force distribution on the substrate is over all parts of the substrate equal and independent of the seams, this improves the quality of the resulting imprinting product.

In one embodiment the at least one master is positioned such that the at least one textured area of the at least one master is oriented away from the waveguiding systems and/or the rear side of at least one of the masters is at least partially in contact with the waveguiding system. The term “partially in contact” preferably means in direct contact. In one preferred embodiment at least one master comprises a textured area and the textured area of the at least one master is in direct contact with the waveguiding system. The term “direct contact” means that the rear side of the master is in physical contact with the waveguiding system, no further material (layer, air) is present between waveguiding system and rear side of the at least one master. In this arrangement, the resin can be kept off the textured areas of the masters when it is applied locally to the gaps between the at least two masters. Due to the arrangement of the master faced with the rear side to the waveguiding system, the resulting welding seam is in one plane with the rear side of the masters resulting in a smooth rear side which significantly simplifies handling of the upscaled master e.g. by a vacuum chunk. In one embodiment the light source is a mercury-vapor lamp or a strip of UV-LEDs placed in a row or placed behind a slit curtain and/or the light of the light source is coupled into the waveguiding system via a coupling means. The term “coupling means” means for example a prism and/or an optical grating. Due to the use of coupling means, the position of the light source is independent from the position of the waveguiding system and thus a greater freedom in the arrangement of the different devices is given. In one preferred embodiment, the light source is positioned on the side of the waveguiding system and the light is coupled into the waveguiding system from the side of the waveguiding system.

In one embodiment a force is applied on the at least two masters perpendicular to at least one of the textured areas. For example, this can be a gravitational force brought about by a weight or an air pressure-controlled force that is applied on the outer sides, not in contact with the waveguide, of the at least two masters, or alternatively by use of vacuum channels integrated in the wave-guide plate. Forces are in the region of below 100 N/cm², preferably below 50 N/cm².

In one preferred embodiment the at least two masters are in direct contact to the waveguiding system, whereby the textured area faces the waveguiding system and is in direct contact with it. When a force presses the masters on the waveguiding system, this can increase the coplanarity of the masters within the upscaled master. Pollution with resin and undesired embossments of the welding seams can be avoided and the quality of the upscaled master is increased.

In one embodiment the at least two masters are positioned side by side in view of the propagation direction of the waveguiding system in a lateral distance between 0 and 500 μm to each other. The lateral distance between the masters corresponds to the width of the welding seam between the masters in the later upscaled master. Between different masters, different distances within the upscaled master are thinkable. The distance and thus the welding seams can be used to divide the upscaled master into different units. The welding seams can also be used as a kind of marker to detect the position of the upscaled master in an imprinting process.

In one embodiment, the position of the at least two masters and/or the lateral distance between the at least two masters and/or the vertical distance between the at least two masters and the waveguiding system and/or the amount of photosensitive resin is detected and/or regulated by at least one controlling device. Any kind of controlling device could be used. For example, sensors or cameras with or without further evaluation units (such as computers). When the position of the masters is detected, the positions for the application of the resin is known and the resin can be applied at these positions by a resin application device. In addition, depending on the lateral distance between the masters the amount of resin is controllable and adjusted for each distance. The value of the vertical distance can serve as the basis for the force that is to act on the master. Furthermore, the amount of photosensitive resin can serve as basis for the light intensity which is coupled into the waveguiding system. Furthermore, measured quantities can also be useful to check the quality of the upscaled master that is created. It is also thinkable that limit values are stored, which, when exceeded, prevent starting of the welding process. This will save resources and increase the quality of the upscaled master.

In one embodiment the photosensitive resin is applied via laminating and/or dispensing and/or printing and/or capillary force during the welding process. Locally applying the resin has the advantage that the amount of resin can be well controlled and backside can be kept clean. On the other hand, application of resin via laminating can ensure that all volumes between the masters are filled with resin even without knowledge of the exact positions of the masters.

In one embodiment at least one master comprises a material that is transparent to the light from the light source and acts as a further waveguiding system besides the primary waveguiding system. Due to the further waveguiding system, the light is transported particularly effectively and the amount of loss is reduced. Especial for lager upscaled masters made by a plurality of masters the further waveguiding system ensures an equal light intensity over the entire master arrangement. In addition, the further waveguiding system can initiate the curing process before the resin is in contact with the primary waveguiding system. With this manner of precuring, undesired spreading of resin is further prevented and a better-quality seam can be created.

In one further embodiment the at least two masters and/or the waveguiding system have a surface free energy of less than 15 mN/m measured according to ISO 19403-2:2017. Due to the preferred surface free energy value of the masters and/or the waveguiding system, the risk of undesired spreading of resin to for example a textured area is further reduced. In addition, a low surface free energy of the waveguide reduces the adhesion between the seams and the waveguide, facilitating the removal of the waveguide after the upscaling process. In one embodiment of the invention the waveguiding system as e.g. outlined in EP 3256907 comprises at least partially a relief structure and/or an optical structure and/or a doping. In one embodiment the relief structure corresponds to the relief pattern of the at least one master. For example, the relief structure creates an onset area of the imprinting stamp and is the area of the stamp in which an imprinting process starts. In one further embodiment the waveguiding system comprises at least partially an optical structure, whereby light of the light source is coupled into the waveguiding system via the optical structure. Due to the optical structure, the position for the light coupling is freely selectable. In one further embodiment, the waveguiding system comprises a doping, which allows the light to exit the waveguide system on selected areas. In this embodiment, parts of the masters can be irradiated to avoid pollution with uncured resin. Due to the doping it is also possible to adjust the light intensity of the waveguiding system. Thus, parts of the waveguiding system may have a higher light output than other parts and independent from the contact to the resin.

In one embodiment the waveguiding system has a sheet form and/or is at least partially made of glass, fused silica, quartz, polymer or mixtures of them. It is also possible that the entire waveguiding system is made of glass, fused silica, quartz, polymer or mixtures of them, whereby the waveguiding system is preferably made of one piece. In one other embodiment the waveguiding system is made of different pieces, whereby each piece is made of the same or different material.

In one further embodiment of the invention the waveguiding system comprises at least one sensor device. The sensor device is part of the waveguide itself or a device separated from the waveguide. The sensor device may be connected to a controller unit which controls the amount of photosensitive resin and/or the intensity of the light source and/or the adjustment of the masters and/or the resin application system.

A further subject of the present invention is an upscaled master made by a method mentioned above. The upscaled master comprises at least two masters, whereby at least one master comprises at least partially at least one textured area and whereby in-between the at least two master a welding seam (welded area) is located whereby the height difference between one textured master and the welding seam is less than 5 μm. This means, the upscaled master has a uniform height which is not or barely influenced by the welded areas (seems). Due to this, an accurate upscaled master is created by a plurality of masters without the disadvantages of disturbing welded seems between the different masters. The obtained upscaled master is manufactured by an inexpensive process, whereby the dimensions and the quantities of masters are easily adapted to actual requirements.

In another embodiment the upscaled master is made of a one or more masters in combination with one or more side tiles to enlarge the upscaled master. In one preferred embodiment in-between at least one master one side tile a welding seam (welded area) is located whereby the height difference between this master and the welding seam and/or between welding seam and this side tile is less than 5 μm. This has the advantage of creating an area outside of the masters to gather resin flow. The one or more masters and side tiles can be removed from the upscaled master. In this embodiment the welding seam creates breaking points within the upscaled master. The removed textured masters can be used again to build the same upscaled master (in a further welding process) or to build a different upscaled master. In one preferred embodiment the upscaled master made of one or more masters in combination with one or more side tiles has over the entire surface area of the upscaled master an average height difference of less than 5 μm. The side tiles (or frames) are preferably tiles without any product texture, but can also have same master texture or other texture to control resin flow or imprint gap/pressure. Typically, the side tiles are longer than the master tiles in at least one dimension. In this way, they can help to align the master tiles to a common reference.

Regarding the side tiles reference is made to the (still unpublished) application EP 20188862.5.

In one embodiment the upscaled master is made of a plurality of masters, whereby the masters can be removed from the upscaled master. Also in this embodiment the welded areas create breaking points within the upscaled master. The removed masters can be used again to build the same upscaled master (in a further welding process) or to build a different upscaled master.

In another embodiment the upscaled master has a surface area, whereby over the entire surface area the average height difference is less than 5 μm. This means, the height difference between different masters as well as between welded areas and masters is less than this value. The obtained upscaled master has a flat surface area, which is especially advantageous for a variety of applications.

A further subject of the present invention is an imprinting product obtained by an upscaled master created according to the method above. This means the imprinting product is made via an imprinting process in which an upscaled master is imprinted on a substrate. The upscaled master is made of at least two masters, whereby at least one of the masters comprises a textured area and the obtained product comprises at least partially the inverse relief pattern of the textured area.

A further subject of the present invention is an apparatus suitable for producing an upscaled master created according to the method above. The upscaled master is made of at least two masters, whereby at least one of the masters comprises a textured area.

The apparatus may comprise a light source. In an embodiment, the light source is a source of visible light. In an embodiment, the light source is a source of UV light. In an embodiment, the light source is a source of both UV and visible light. In an embodiment the light source of the apparatus is a Mercury-vapor lamp or a strip of UV-LEDs placed in a row or placed aside of the glass-edges, behind a slit curtain and/or the light of the light source is coupled into the waveguiding system via a coupling means. The term “coupling means” means for example a prism and/or an optical grating. Due to the use of coupling means, the incoupling of light into the waveguide is more efficient (resulting in higher intensity), which is an advantage. Additionally, the light source can be placed in a variety of orientations, allowing more freedom in the arrangement. In an embodiment, the light source is positioned on the side of the waveguiding system and the light is coupled into the waveguiding system from the side of the waveguiding system.

The apparatus may comprise a waveguiding system. In one embodiment the waveguiding system has a sheet form and/or is at least partially made of glass, fused silica, quartz, polymer or mixtures of them. In an embodiment, the entire waveguiding system is made of glass, fused silica, quartz, polymer or mixtures of them, whereby the waveguiding system is made of one piece. In another embodiment the waveguiding system is made of different pieces, whereby each piece is made of the same or different material. The pieces may be connected with an adhesive with a refractive index that differs from the refractive index of the material of the pieces by at most +/−0.03, preferably by at most +/−0.01.

In an embodiment, the waveguiding system of the apparatus according to the invention comprises a sensor device. The sensor device may be a part of the waveguide system itself or a device separated from the waveguide system. The sensor device may be connected to a controller unit which controls the amount of photosensitive resin and/or the intensity of the light source and/or the adjustment of the masters and/or the resin application system.

In one further embodiment the waveguiding system of the apparatus according to the invention comprises at least partially an optical structure, whereby light of the light source is coupled into the waveguiding system via the optical structure. Due to the optical structure, the position for the light coupling is freely selectable. In one further embodiment, the waveguiding system of the apparatus comprises a doping, which allows the light to exit the waveguide system on selected areas. In this embodiment, parts of the masters can be irradiated to avoid pollution with uncured resin. Due to the doping it is also possible to adjust the light intensity of the waveguiding system of the apparatus. Thus, parts of the waveguiding system of the apparatus may have a higher light output than other parts and independent from the contact to the resin.

In one further embodiment of the invention the waveguiding system comprises at least one sensor device. The sensor device is part of the waveguide itself or a device separated from the waveguide. The sensor device may be connected to a controller unit which controls the amount of photosensitive resin and/or the intensity of the light source and/or the adjustment of the masters and/or the resin application system.

The apparatus may comprise a means for exerting force onto the outer side, not in contact with the waveguide, of the at least two masters. In an embodiment, the means to exert force is a weight that can be released onto the at least two masters. In an embodiment, the means to exert force is a pneumatically or hydraulically driven stamp. In an embodiment, the means to exert force is an mechanically or electrically driven stamp.

The apparatus may comprise a means to apply photosensitive resin to the at least two masters. In an embodiment the means can be a slot-dye coater, screen-printer or possibly even a spin-coater. In an embodiment, the means to apply photosensitive resin can be a dispensing device that drops or prints liquid resin on the rear sides of the at least two masters. For lamination of the rear sides with the photosensitive resin the dispensing device may be combined with a movable doctor blade or a movable roller. In an embodiment, the means to apply photosensitive resin can be at least one movable nozzle comparable to the nozzle of an inkjet printer that releases photosensitive resin all over the rear sides of the at least two masters or locally. In an embodiment the resin flows over the texture surface by use of capillary force.

The apparatus may comprise a controlling device suitable for detecting and controlling the position of the at least two masters and/or the lateral distance between the at least two masters and the waveguiding system and/or the amount of photosensitive resin. Any kind of controlling device could be used. For example, sensors or cameras with or without further evaluation units (such as computers). When the position of the masters is detected, the positions for the application of the resin is known and the resin can be applied at these positions by a means to apply resin. In addition, depending on the lateral distance between the masters the amount of resin is controllable and adjusted for each distance. The value of the vertical distance can serve as the basis for the force that has to be exerted on the master by the means for exerting force. Furthermore, the amount of photosensitive resin can serve as basis for the light intensity which is coupled into the waveguiding system. Furthermore, measured quantities can also be useful to check the quality of the upscaled master that is created. It is also thinkable that limit values are stored, which, when exceeded, prevent starting of the welding process. This will save resources and increase the quality of the upscaled master.

The apparatus may comprise one or more lifting devices suitable for positioning the at least two masters on the surface of the waveguiding system and/or for lifting the upscaled master from the surface of the waveguiding system. The one or more lifting devices may be one or more robots. The one or more lifting devices may be one or more delta robots. The one or more lifting devices may be equipped with vacuum chunks to temporarily adhere to smooth surfaces. The one or more lifting devices may be equipped with electromagnets to temporarily adhere to ferromagnetic items.

The apparatus may comprise a housing which protects the surface of the waveguide system, the masters and the resin from soiling by e.g. dust. The housing may furthermore be non-transparent for the light used during the curing process in order to protect employees from intense light, and to prevent this type of light from external sources from entering the setup. At least parts of the housing may be removable or the housing may comprise doors in order to access the interior of the apparatus. For security reasons, the housing may comprise a switch which only allows the light source to be switched on when the housing is entirely closed.

The invention is explained now in more detail with reference to the following figures, wherein the scope of the invention is not limited by the figures:

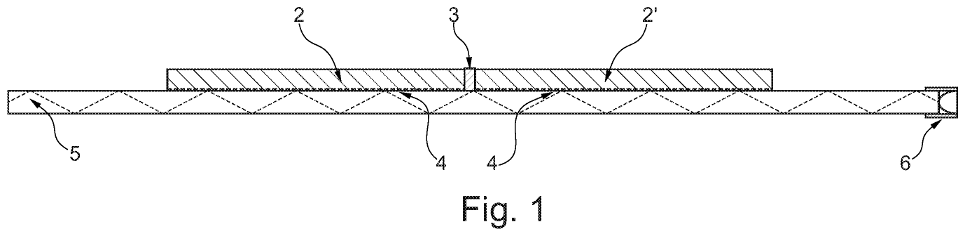

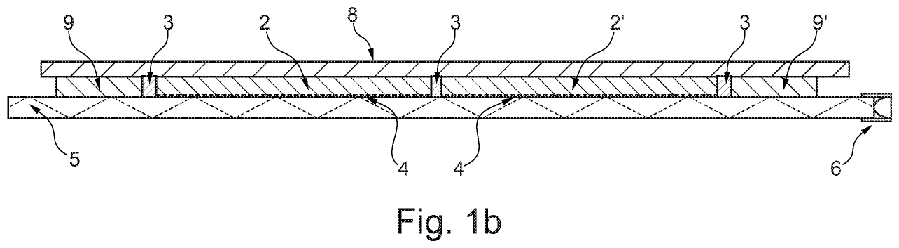

FIG. 1 shows schematically an arrangement for a welding method.

FIG. 1b shows schematically an arrangement for a welding method using a back-plate for stability of the upscaled master as well as using side tiles.

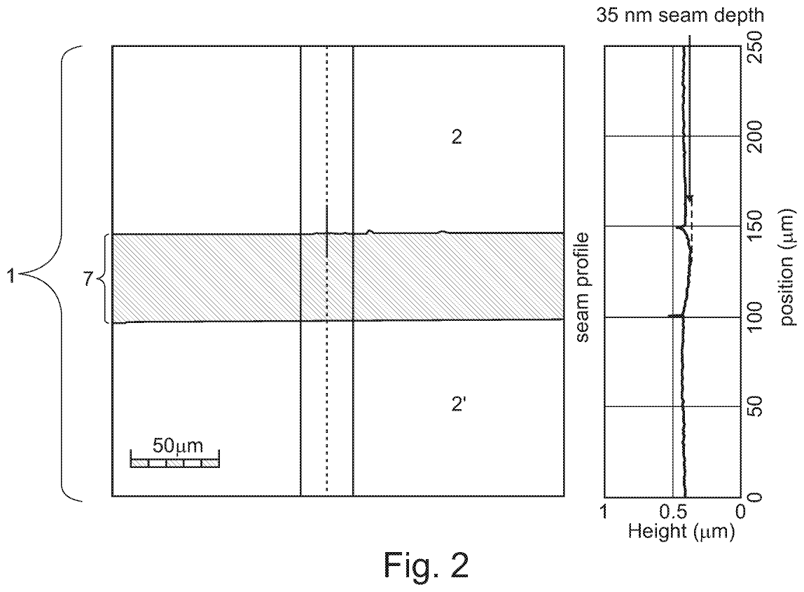

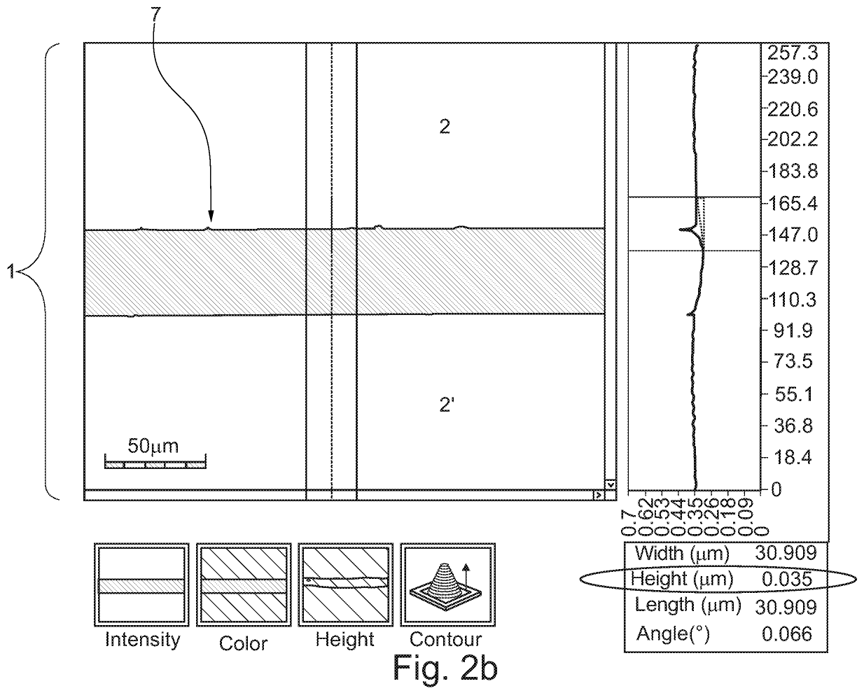

FIGS. 2 and 2b shows an image of a part of an upscaled master with a welded area (welding seam).

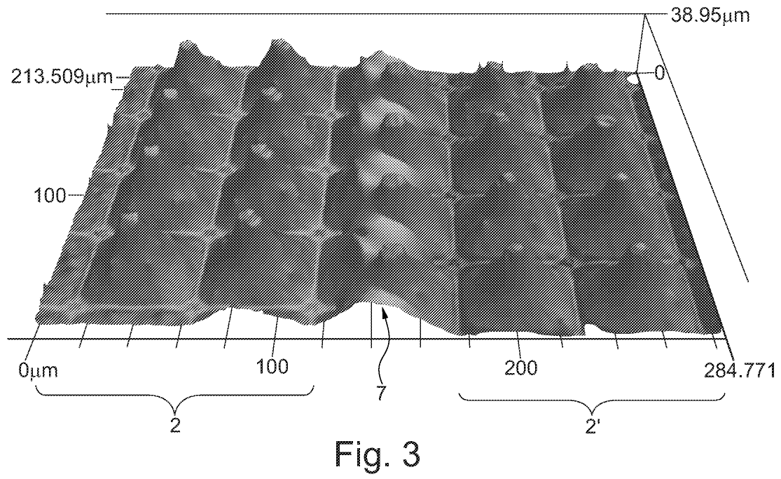

FIG. 3 shows schematically a 3D representation of a height profile measurement of a welded upscaled master.

In FIG. 1 a method for making an upscaled master is shown. In FIG. 1 two masters 2, 2′are positioned on and in contact to a waveguiding system 5 with a textured area 4 facing the waveguiding system 5. A curable photosensitive resin 3 is present between the two masters 2, 2′. A light source 6 is positioned in an edge area of the waveguiding systems 5 and guides the light within the waveguiding system 5. Where the curable photosensitive resin 3 is in contact to the waveguiding system 5 the light leaves the waveguiding system 5 and cures the resin 3. The cured resin welds the masters 2, 2′ together via a welding seam (which is a welded area) to form the upscaled master.

In FIG. 1b a back-plate 8 has been mounted on the masters 2 and 2′ and side tiles 9 and 9′. The back-plate 8 can be used for handling stability. The back-plate material can be any sheet, for instance a polymer foil, glass plate or metal sheet. The mounting can be for instance done using a lamination step in combination with a glue, pressure sensitive or curable resin. The side-tiles 9 and 9′ can be used to enlarge the scaled-up master. The side-tiles 9 and 9′are mounted on the master by cured resin 3 and thus by the same way than further masters are connected together by the curable resin 3. Also here a seam is created between master and side tiles, whereby the height difference between one master and the welding seam is also preferably less than 5 μm. In one preferred embodiment the upscaled master (1) made by the at least two masters (2. 2′) and at least one side tile (9, 9′) has over the entire surface area an average height difference of less than 5 μm. The area outside of the masters 2 and 2′ can be used to gather resin.

In FIG. 2 and also in FIG. 2b a laser microscopy image of an upscaled master 1 is shown. In this image two masters 2, 2′ are welded together by a welding seam 7. The welding seam 7 is made of cured resin. The height profile on the right side of FIG. 2 shows that the height of the welding seam 7 deviates less than 50 nm from the planes of the masters 2, 2′.

FIG. 3 represents a height profile measurement of two textured masters 2, 2′ that have been welded together as described in the specification. The welding seam 7 is in-between the two masters 2, 2′ and the height of the welding seam 7 corresponds to the height of the masters 2, 2′.

1. A welding method for creating an upscaled master for an imprinting process, comprising:
welding at least two masters together, wherein at least one master comprises at least partially at least one textured area, applying a photosensitive resin is at least between the at least two masters,
guiding light of a light source within a waveguiding system and cures the photosensitive resin at least between the at least two masters when the photosensitive resin comes into contact with the waveguiding system.

2. The welding method according to claim 1, wherein the at least two masters are positioned such that the at least one textured area of the at least two masters is oriented towards the waveguiding systems and/or at least one of the masters is at least partially in contact with the light guiding system.

3. The welding method according to claim 1, wherein the light source is a mercury-vapor lamp or a strip of UV-LEDs and/or the light of the light source is coupled into the waveguiding system via a coupler.

4. The welding method according to claim 1, wherein a force is applied on the at least two masters perpendicularly to at least one of the textured areas.

5. The welding method according to claim 1, wherein the at least two masters are positioned side by side in a lateral distance between 0 and 500 μm.

6. The welding method according to claim 1, wherein a position of the at least two masters and/or a lateral distance between the at least two masters and/or a vertical distance between the at least two masters and the waveguiding system and/or an amount of photosensitive resin is detected and/or regulated by at least one controlling device.

7. The welding method according to claim 1, wherein the photosensitive resin is added via laminating and/or dispensing and/or printing and/or capillary force.

8. The welding method according to claim 1, wherein at least one master comprises a material that is transparent to the light from the light source and acts as a further waveguiding system.

9. The welding method according to claim 1, wherein the at least two masters and/or the waveguiding system have a surface free energy of less than 15 mN/m measured according to contact angle measurement according to ISO 19403-2:2017.

10. The welding method according to claim 1, wherein the waveguiding system comprises at least partially a relief structure and/or an optical structure and/or a doping.

11. The welding method according to claim 1, wherein the waveguiding system has a sheet form and/or is at least partially made of glass, fused silica, quartz, polymer or mixtures thereof.

12. The welding method according to claim 1, wherein the waveguiding system comprises at least one sensor device.

13. A unsealed master made by a method according to claim 1, wherein the upscaled master comprises at least two masters, wherein at least one master comprises at least partially at least one textured area and wherein in-between the at least two master a welding seam is located wherein a height difference between one textured master and the welding seam is less than 5 μm.

14. The upscaled master according to claim 13, wherein the upscaled master comprises at least one side tile.

15. The upscaled master according to claim 13, wherein the upscaled master has a surface area, wherein over an entire surface area an average height difference is less than 5 μm.

16. Imprinting product made by a upscaled master according to claim 13.

17. An apparatus for making an upscaled master by carrying out the welding method according to claim 1.
